(19) United States
(12) Patent Application Publication
(10) Pub. No.: US 2017/0271001 A1
(43) Pub. Date: Sep. 21, 2017

(54) DETERMINING A CURRENT IN A MEMORY ELEMENT OF A CROSSBAR ARRAY

(71) Applicant: Hewlett Packard Enterprise Development LP, Houston, TX (US)

(72) Inventors: Naveen Muralimanohar, Santa Clara, CA (US); Rajeev Balasubramonian, Palo Alto, CA (US); Martin Foltin, Fort Collins, CO (US)

(21) Appl. No.: 15/500,040

(22) PCT Filed: Jan. 30, 2015
(86) PCT No.: PCT/US2015/013877

§ 371 Date: Jan. 28, 2017

(51) Int. Cl. G11C 13/00

(52) U.S. Cl. CPC G11C 13/003; G11C 13/0069; G11C 13/004

(57) ABSTRACT

A method of determining a current in a memory element of a crossbar array is described. In the method, a number of pre-access operations are initiated. Each pre-access operation includes discarding a previously stored sneak current, determining a new sneak current for the crossbar array, discarding a previously stored sneak current, and storing the new sneak current. In the method, in response to a received access command, an access voltage is applied to a target memory element of the crossbar array and an element current for the target memory element is determined based on an access current and a stored sneak current.

### BACKGROUND

Memory arrays are used to store data. A memory array may be made up of a number of memory elements. Data may be stored to memory elements by assigning logic values to the memory elements within the memory arrays. For example, the memory elements may be set to 0, 1, or combinations thereof to store data in a memory element of a memory array. Much time and effort has been expended in designing and implementing nanoscale memory arrays. In some examples the nanoscale memory arrays may be arranged in a crossbar array where a first number of conducting lines intersect a second number of conducting lines to form a grid where memory elements are placed at each intersection.

### BRIEF DESCRIPTION OF THE DRAWINGS

The accompanying drawings illustrate various examples of the principles described herein and are a part of the specification. The illustrated examples are given merely for illustration, and do not limit the scope of the claims.

FIG. 1 is a diagram of a system for determining a current in a memory element of a crossbar array, according to one example of the principles described herein.

FIG. 2 is a diagram of a crossbar array for use in the system as depicted in FIG. 1, according to one example of the principles described herein.

FIGS. 3A and 3B are diagrams of a system for determining a current in a memory array with the pre-access engine as part of the memory controller and memory, respectively, according to one example of the principles described herein.

FIG. 4 is a flowchart of a method for determining a current in a memory element of a crossbar array, according to one example of the principles described herein.

FIG. 5 is a flowchart of a method for determining a current in a memory element of a crossbar array, according to another example of the principles described herein.

FIG. 6 is a diagram of a pre-access engine for determining current in a memory element of a crossbar array, according to one example of the principles described herein.

Throughout the drawings, identical reference numbers designate similar, but not necessarily identical, elements.

### DETAILED DESCRIPTION

Increasingly smaller computing devices have led to an increased focus on developing smaller components, such as memory arrays. Crossbar arrays are one example of reduced-size memory arrays. Crossbar arrays of memory elements such as memristors may be used in a variety of applications, including non-volatile solid state memory, programmable logic, signal processing, control systems, pattern recognition, and other applications. A crossbar array includes a first set of conducting lines that intersect a second set of conducting lines, in an approximately orthogonal orientation for example. A memory cell is placed at each intersection. A memory cell may include a memory element to store information and a selector to allow or prevent current flow through the memory element. In this example, a number of memory elements may share a particular first line and another number of memory elements may share a particular second line.

Each memory element can represent two logic values, for example a 1 and a 0. Memory elements such as memristors may use resistance levels to indicate a particular logic value. In using a memristor as an element in a memory array, a digital operation is emulated by applying an activation energy such as voltage pulses of different values or polarities to place the memristor in a “low resistance state” which resistance state is associated with a logical value, such as “1.” Similarly, a voltage pulse of a different polarity, or different value, may place the memristor in a “high resistance state,” which resistance state is associated with another logical value, such as “0.” Each memristor has a switching voltage which refers to a voltage potential across a memristor which effectuates a change in the resistance state of the memristor. For example, a switching voltage of a memristor may be between 1-2 volts (V). In this example, a voltage potential across the memristor that is greater than the switching voltage (i.e., the 1-2V) causes the memristor to change between resistance states. While specific reference is made to voltage pulses other activation energies may also be used such as current energy.

To determine what resistance state, and corresponding logic value, is indicated by a memristor, an output current may be collected and analyzed. For example, if a write voltage is applied across a target memory element, a write current passing through the target memory element may be collected. Based on the write voltage and the collected write current, a resistance level of the memristor and corresponding written logic value may be ascertained. Similarly, if a read voltage is applied across a target memory element, a current passing through the target memory element may be collected. Based on the read voltage and the collected read current, a resistance level of the memristor and the corresponding stored logic value may be ascertained.

In these examples, a first portion of an access voltage (i.e., read voltage or write voltage) is applied to a target first line and a second portion of the access voltage (i.e., read voltage or write voltage) is applied to a target second line that corresponds to the target memory element such that an overall voltage drop across the target memory element is large enough that the target memory element can be read from or written to. The second portion of the access voltage may be the same polarity or different polarity from the first portion as long as the overall voltage potential across the memory element is at least as great as the access voltage. An output current is then read that, along with the access voltage, can be used to determine the resistance of the target memory element and the corresponding logic value. However, while crossbar memory arrays may offer high density storage, certain characteristics may affect their usefulness in storing information.

For example, in applying a portion of an access voltage to a target first line and another portion of the access voltage to a target second line, other memory elements that fall along these target lines may also see a voltage drop, albeit a voltage drop smaller than the voltage drop across the target memory element. The voltage potential across these partially-selected memory elements generates a current path in the crossbar array. These additional current paths are referred to as sneak currents and are undesirable as they are noise to the intended target output current. Large sneak currents may lead to a number of issues such as saturating the current of driving transistors and increasing power consumption. Moreover, large sneak currents may introduce large amounts of noise which may lead to inaccurate or ineffective memory reading and writing operations.

In some examples, a selector may be placed serially in front of a memory element. The selector may have a threshold voltage. An applied voltage less than the threshold voltage does not pass through to the corresponding memory element and thus a portion of a sneak current may be reduced. However, even while an applied voltage may be less than the threshold voltage of the selector, a small amount of current may still flow through the selector and memory element.

The system and method described herein may alleviate these and other complications. More specifically, the present systems and methods describe determining an output current that is used to determine a resistance state of a memory element. First, an operation is carried out that determines the sneak current passing through a crossbar array. This operation may be carried out independently from an access operation executed on the crossbar array. The sneak current may be stored using a column granularity. That is, the sneak current may be collected along and stored for one of the column lines of a crossbar array. Then, when an access (i.e., read or write) request is received for a memory element in a column, the sneak current for that column is subtracted from an access current. By subtracting the sneak current from the access current, an actual current passing through a target memory element is acquired and a more efficient and accurate determination of memory element resistance is determined. Moreover, the system and method described herein decouples the sneak current determination from an access current determination. Such decoupling may improve access latency as after an access command is received, there is no determination of a sneak current and a determination of access current, but rather just a determination of access current; the sneak current having been previously determined. The previously determined sneak current is then called and subtracted from the access current to determine an element current.

The present disclosure describes a method for determining a current in a memory element of a crossbar array. In the method, a number of pre-access operations are initiated. For each pre-access operation, a previously stored sneak current is discarded, a new sneak current for the crossbar array is determined, and the new sneak current is stored. Then, in response to receiving an access command, an access voltage is applied across a target memory element of the crossbar array. An element current is determined for the target memory element based on an access current and a stored sneak current.

The present disclosure describes a system for determining a current in a memory element of a crossbar array. The system includes a crossbar array of memory elements. The crossbar array includes a number of first lines and a number of second lines intersecting the first lines. A memory element is located at each intersection of a first line and a second line. The system also includes sensing circuitry coupled to the number of second lines to determine an element current for a memory element by subtracting a sneak current from an access current. The system also includes a memory controller communicatively coupled to the crossbar array. The memory controller initiates an access operation. The system also includes a pre-access engine to initiate a pre-access operation, separate from an access operation, to determine a sneak current for the crossbar array.

The present specification describes a non-transitory machine-readable storage medium encoded with instructions executable by a memory controller. The machine-readable storage medium includes instructions to, during a pre-access operation, discard a previously stored sneak current, determine a new sneak current for the crossbar array, and store the new sneak current for the crossbar array. The machine-readable storage medium also includes instructions to, responsive to an access command, determine an element current for the target memory element based on an access current and a stored sneak current.

The systems and methods described herein may allow for determination of an element current that is free of the influence of sneak current. Also, by determining the sneak current separately from an access command, read and write latency is improved as the sneak current is not determined during the read or write operation, but prior to either event. Accordingly a more efficient and accurate accessing of data, i.e., reading and writing, can be achieved by speculatively determining background current previous to reception of an access command. Moreover, in determining the sneak current separately from the access command, a memory controller can flexibly determine when to calculate a sneak current so as to avoid conflict with read and write operations.

As used in the present specification and in the appended claims, the term “memristor” may refer to a passive two-terminal circuit element that changes its electrical resistance under sufficient electrical bias. A memristor may receive an access voltage which may be a read voltage or a write voltage.

Further, as used in the present specification and in the appended claims, the term “target” may refer to a memory element that is to be written to or read from. A target first line and a target second line may be first lines and second lines that correspond to the target memory element. A target memory element may refer to a memory element with a closed selector as opposed to an open selector.

Still further, as used in the present specification and in the appended claims, the term “partially-selected memory element” may refer to a memory element that falls along a target first line or a target second line that is not a target memory element. The partially-selected memory elements may have a voltage drop that is less than a voltage drop of the target memory element. A partially-selected memristor may receive either the first portion of the access voltage passed through a target first line or the second portion of the access voltage passed through a target second line. Memory elements that do not fall along either the target first line or target second line are unselected memory elements.

Still further, as used in the present specification and in the appended claims the term “access voltage” may refer to a voltage that is applied across a memory element. The access voltage may be a write voltage that is larger than a switching voltage of a memory element, or may be a read voltage that is less than the switching voltage of the memory element. By comparison, a non-access voltage may refer to a voltage that is not greater than either a read voltage or a write voltage. The access voltage may be greater than a threshold voltage for a selector, the threshold voltage being a voltage sufficient to open a selector and a non-access voltage may be less than the threshold voltage for a selector.

Still further, as used in the present specification and in the appended claims, the terms “first lines” and “second lines” may refer to distinct conducting lines, such as wires, that are formed in a grid and apply voltages to the memory elements in the array. A memory element may be found at the intersection of a first line and a second line. In some examples, the first lines and second lines may be referred to as row lines and column lines.

Yet further, as used in the present specification and in the appended claims, the term “a number of” or similar language may include any positive number including 1 to infinity; zero not being a number, but the absence of a number.

In the following description, for purposes of explanation, numerous specific details are set forth in order to provide a thorough understanding of the present systems and methods. It will be apparent, however, to one skilled in the art that the present apparatus, systems, and methods may be practiced without these specific details. Reference in the specification to “an example” or similar language indicates that a particular feature, structure, or characteristic described is included in at least that one example, but not necessarily in other examples.

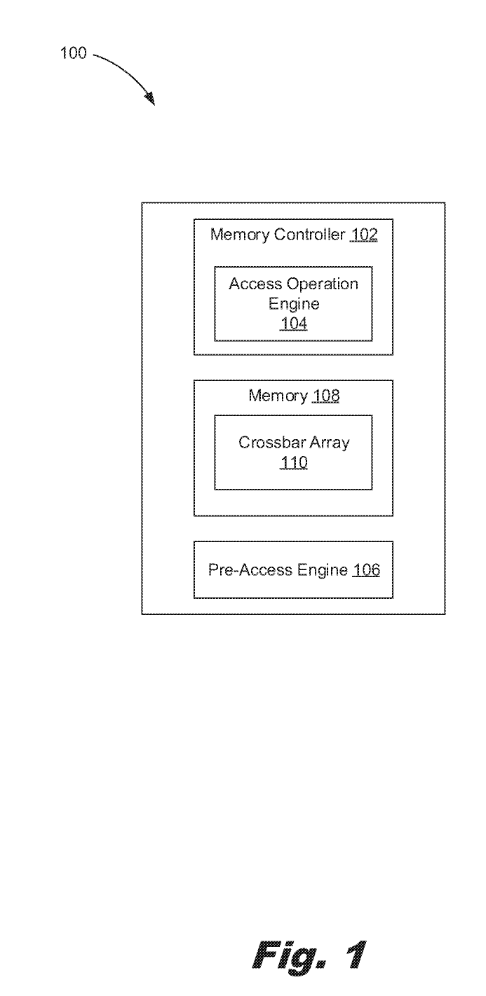

FIG. 1 is a diagram of a system (100) for determining a current in a memory element in a crossbar array (110), according to one example of the principles described herein. The system (100) may be implemented in an electronic device. Examples of electronic devices include servers, desktop computers, laptop computers, personal digital assistants (PDAs), mobile devices, smartphones, gaming systems, and tablets, among other electronic devices. The system (100) may be utilized in any data processing scenario including, stand-alone hardware, mobile applications, through a computing network, or combinations thereof. Further, the system (100) may be used in a computing network, a public cloud network, a private cloud network, a hybrid cloud network, other forms of networks, or combinations thereof.

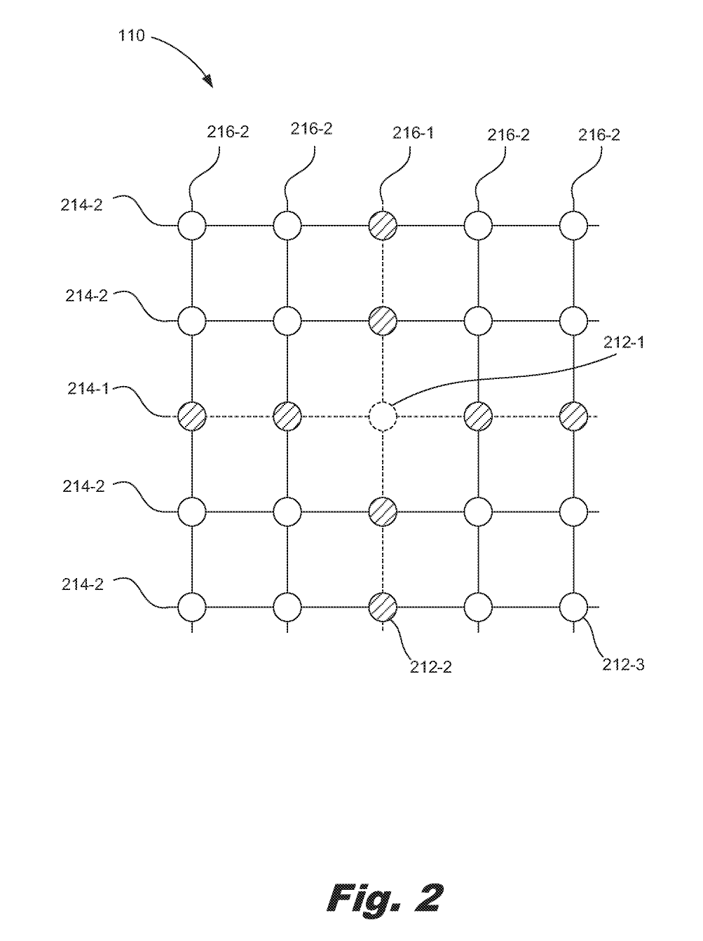

The system (100) may include memory (108), which includes a crossbar array (110). The crossbar array (110) may be part of a larger memory array (108). For example, a memory array (108) may be divided into banks, which banks may be divided into sub-banks, which sub-banks may be divided into sub-arrays, which sub-arrays may be divided into mats. In one example, the crossbar array (110) may be a sub-array and may have a corresponding memory controller (102). More detail regarding the crossbar array (110) of memory (108) is provided in connection with FIG. 2.

The system (100) may also include a memory controller (102) to determine a current passing through a target memory element. The memory controller (102) executes instructions to provide the described features and functionalities as well as others. The memory controller (102) may be coupled to or include the memory resources that store the instructions. The memory controller (102) may be an electrical device or component that, in addition to other functions, operates or controls a memory device. The memory controller (102) may include at least one of circuitry, a processor, or other electrical component. The memory controller (102) further includes a number of engines used in the implementation of the systems and methods described herein. The engines refer to a combination of hardware such as circuitry and program instructions to perform a designated function.

The memory controller (102) may include an access operation engine (104). The access operation engine (104) may generate a command that instructs the memory (108) to carry out an access operation. Responsive to such a command, circuitry in the memory (108) may apply access voltages such as read voltages and write voltages to the crossbar array (110) to ascertain the resistance level, and corresponding logic value of memory elements within the crossbar array (110).

The system (100) also includes a pre-access engine (106) to initiate a pre-access operation to determine a sneak current for the crossbar array (110). The pre-access operation may be separate, or independently executed in time, from an access operation. As described above, in some examples, a sneak current is determined prior to reception of an access command, thus decoupling the pre-access operation, from which a sneak current is determined, from an access operation, from which an access current is determined. Doing so improves access latency such that a pre-access command may be issued and a pre-access operation executed before an access command is received. Accordingly, the pre-access engine (106) may determine a period when the sneak current is to be calculated.

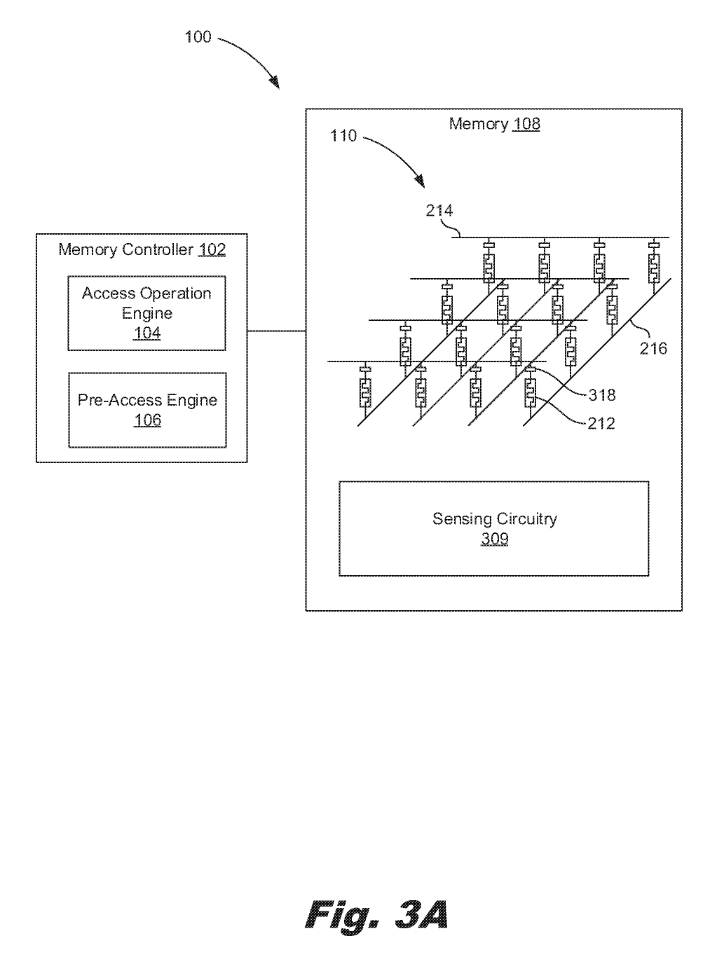

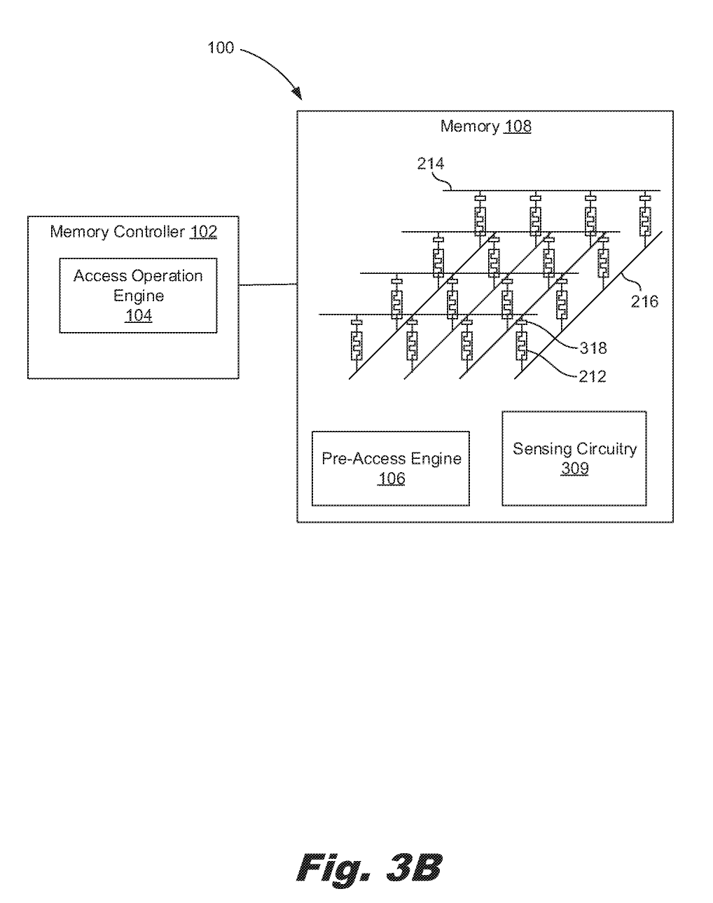

In some examples, the pre-access engine (106) may be implemented as circuitry. For example, as described in FIG. 3B, the pre-access engine (106) may be part of the circuitry included in a sub-array of a memory array (108). More detail regarding the pre-access engine (106) as part of memory (108) is provided below in connection with FIG. 3B.

In some examples, the pre-access engine (106) may be an instruction that is executed by the memory controller (102). For example, as described in FIG. 3A, the memory controller (102) may execute a command to perform a pre-access operation. More detail regarding the pre-access engine (106) as part of the memory controller (102) is provided below in connection with FIG. 3A.

FIG. 2 is a diagram of a crossbar array (110) according to one example of the principles described herein. As described above, the crossbar array (110) may include first lines (214-1, 214-2) and second lines (216-1. 216-2). The intersection of each first line (214-1, 214-2) and second lines (216-1, 216-2) may define a memory element (212), such as a memristor; a memristor being a non-volatile memory element. A memristor can be used to represent a number of bits of data. For example, a memristor in a low resistance state may represent a logic value of “1.” The same memristor in a high resistance state may represent a logic value of “0.” Each logic value is associated with a resistance state of the memristor such that data can be stored in a memristor by changing the resistance state of the memristor. This may be done by applying an access voltage to a target memristor by passing voltages to target lines that correspond to the target memristor.

A memristor is a specific type of memory element (212) that can change resistances by transporting dopants within a switching layer to increase or decrease the resistivity of the memristor. As a sufficient voltage is passed across the memristor the dopants become active such that they move within a switching layer of the memristor and thereby change the resistance of the memristor.

A memristor is non-volatile because the memristor maintains its resistivity, and indicated logic value even in the absence of a supplied voltage. In this manner, the memristors are “memory resistors” in that they “remember” the last resistance that they had. Memristance is a property of the electronic component referred to as a memristor. If charge flows in one direction through a circuit, the resistance of that component of the circuit will increase. If charge flows in the opposite direction in the circuit, the resistance will decrease. If the flow of charge is stopped by turning off the applied voltage, the component will “remember” the last resistance that it had, and when the flow of charge starts again the resistance of the circuit will be what it was when it was last active. A memristor is a resistor device whose resistance can be changed.

For simplicity, a few memory elements (212) have been identified with reference numbers, but all memory elements (212) in the crossbar array (110) may share similar characteristics. One such characteristic is a switching voltage, V, which is defined as the voltage drop across a memory element (212) that causes the memory element (212) to switch states.

To select a target memory element (212-1) indicated in FIG. 2 by a dashed unfilled circle, the voltage potential may be applied across the target memory element via the target first line (214-1) and target second line (216-1) that correspond to the target memory element (212-1). For example, a target first line (214-1) may supply a first portion of a voltage to the target memory element (212-1) while a target second line (216-1) applies a second portion of a voltage to the target memory element (212-1). The difference between the first portion and second portion generating a voltage potential across the target memory element (212-1). The applied voltage may be either a voltage less than the switching voltage of the target memory element (212-1), i.e., a read voltage; or may be greater than the switching voltage of the target memory element (212-1), i.e., a write voltage. In some examples, the voltage supplied by the target first line (214-1) may be the total voltage value and the target second line (216-1) may be grounded.

As depicted in FIG. 2, a number of other memory elements that are not the target memory element (212-1) may fall along one of the target first line (214-1) or the target second line (216-1). In FIG. 2, these partially-selected memory elements (212-2) are represented as cross-hatched circles. For simplicity, one example of a partially-selected memory element (212-2) is indicated by a reference number. Memory elements (212-3) that do not fall along either the target first line (214-1) or the target second line (216-1) are unselected memory elements (212-3) and are represented as unfilled circles. Put another way, unselected memory elements (212-3) may be defined at the intersection of a non-target first line (214-2) and a non-target second line (216-1). For simplicity one example of an unselected memory element (212-3) is represented by a reference number.

FIG. 3A is a diagram of a system (100) for determining a current in a memory array (108) with the pre-access engine (106) as part of the memory controller (102), according to one example of the principles described herein. As described above, the memory (108) may include a crossbar array (110). The crossbar array (110) may include a number of first lines (214), a number of second lines (216), a number of memory elements (212), and a number of selectors (318).

A selector (318) is a component that either allows current to flow through the memory element (212) or prevents current from flowing through the memory element (212). For example, the selector (318) may have a threshold voltage, Vₜₕ. When a voltage applied along a first line (214) is less than the threshold voltage, the selector (318) is open such that no current flows to a corresponding memory element (212). By comparison, when a voltage applied along a first line (214) is at least as great as the threshold voltage, the selector (318) closes such that current readily flows to a corresponding memory element (212). In this fashion, the selector (318) reduces the sneak current flowing through a crossbar array (110) by preventing current flow through unselected memory elements (212). Notwithstanding the selector (318), a sub-threshold current may flow through each memory element (212).

The memory (108) may include sensing circuitry (309) that is communicatively coupled to the crossbar array (110). More specifically, the sensing circuitry (309) may be coupled to the number of second lines (216) to determine an element current for a memory element (212). For example, as a voltage is applied across a particular memory element (212) a current may be generated. This current may be collected along a second line (216) corresponding to the particular memory element (212). Accordingly, the sensing circuitry (309) may collect and store a sneak current, for each second line (216), based on a pre-access voltage that is applied to the crossbar array (110), for example along all the first lines (214) of the crossbar array (110).

Then, in response to an access command, an access voltage may be applied across a target memory element (FIG. 2, 212-1). In this example, the sensing circuitry (309) may collect the access current, which is reflective of the application of the access voltage across the target memory element (FIG. 2, 212-1) and a voltage potential across non-target memory elements (FIG. 2, 212-2, 212-3). The sensing circuitry (309) may then call from a sample and hold circuit, the sneak current for the target second line (FIG. 2, 216-1) and subtract the sneak current from the access current to determine an element current for the target memory element (FIG. 2, 212-1). This element current may then be used to determine a resistance state, and corresponding logic value, associated with the target memory element (FIG. 2, 212-1).

The sample and hold circuit may include a capacitor to store a current that is representative of the sneak current collected. In some examples, a switch is disposed along a line between a second line selector and the sample and hold circuit such that the sample and hold circuit in one mode is connected to the crossbar array (110) to store a sneak current and in another mode is not connected to the crossbar array (110), for example, when an access current is being passed. When the sneak current is not connected to the crossbar array (110), the sample and hold circuit may be coupled to a subtraction circuit. In some examples, the sample and hold circuit may hold a stored sneak current for a set period of time. Once the set period of time has expired, a sneak current for the target second line (FIG. 2, 216-1) is re-calculated. In other words, a sneak current may be called and used for an access operation, such as a read operation or a write operation, that occurs within the set period of time before the sample and hold circuit no longer holds the sneak current.

The sensing circuitry (309) may also include a subtraction circuit that subtracts the stored sneak current from a measured access current. Accordingly, the subtraction circuit is selectively coupled, via switches, to a second line selector, the source of the access current, and the sample and hold circuit, the source of the sneak current. The subtraction circuit may include a number of switches and transistors to subtract one current, i.e., the sneak current from the sample and hold circuit from the access current, from the crossbar array (110).

The sensing circuitry (309) may include other components to determine a resistance level of the target memory element (FIG. 2, 212-1). For example, the sensing circuitry (309) may include a detection circuit (not shown) to compare the element current to a reference current to determine the resistance value of the target memory element (FIG. 2, 212-1).

The sensing circuitry (309), and more specifically the switches, may be controlled by the memory controller (102) which receives executable instructions from memory resources that indicates when the processor should open and close the switch. The switch allows sensing circuitry (309) in one mode to collect and store a sneak current and in another mode to collect an access current and subtract from the access current the previously measured sneak current

Returning to the system (100), in the example depicted in FIG. 3A, the pre-access engine (106) is part of the memory controller (102). In this example, the pre-access engine (106) may determine that a pre-access command should be issued based on information about past requests, future requests, or combinations thereof. In other words, the pre-access engine (106) as part of the memory controller (102) may access information about the crossbar array (110) including the read and write queues, and may use this information to determine when to issue a pre-access command. Still further, the pre-access engine (106) as part of the memory controller (102) may issue a pre-access command after a change has occurred to the crossbar array (110). For example, in a crossbar array (110) temperature variations and different operating conditions may affect the sneak current, or response to a voltage. Accordingly, after such a change, the memory controller (102) may determine that a new sneak current value should be determined. Accordingly, the memory controller (102) may send such a request to the memory (108). Similarly, as the memory (108) characteristics may change over time, the pre-access engine (106) as part of the memory controller (102) may issue a pre-access command after a set period of time has passed. Similarly, as the capacitor that stores the sneak current may leak its value over time, the memory controller (102) may issue a pre-access command after a set period of time has passed. In some examples, the pre-access command may be issued after a stored sneak current has been accessed a determined number of times, for example in determining an element current.

FIG. 3B is a diagram of a system (100) for determining a current in a memory array (108) with the pre-access engine (106) as part of the memory (108), according to one example of the principles described herein. In this example, the pre-access engine (106) may initiate a pre-access operation based on a number of heuristics. Examples of such heuristics include determining that a number of accesses to the crossbar array (110) have been executed or that a write operation has been executed on the crossbar array (110), which write operation changes the sneak current characteristics of the crossbar array (110). In this example, once the pre-access engine (106) as circuitry determines that a pre-access operation should be carried out, the pre-access engine (106) may trigger a voltage source to apply the pre-access voltage from which a sneak current is determined.

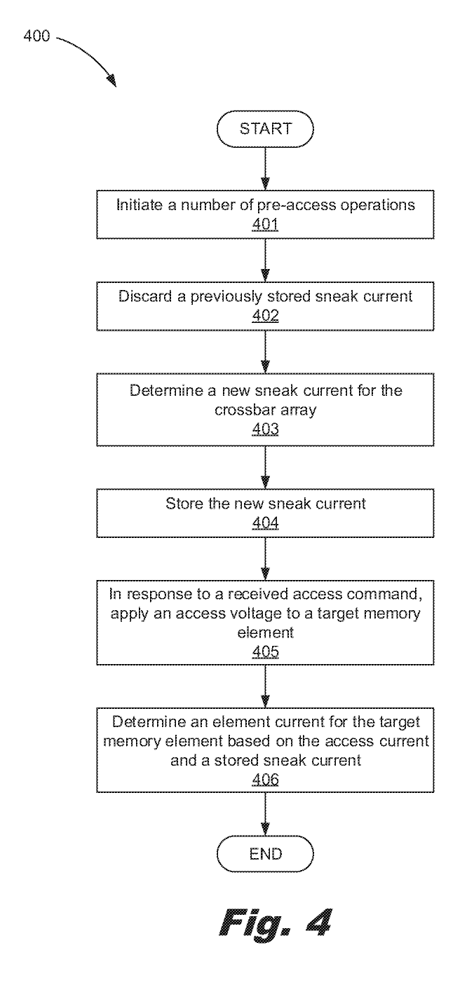

FIG. 4 is a flowchart of a method (400) for determining a current in a memory element (FIG. 2, 212) of a crossbar array (FIG. 1, 110), according to one example of the principles described herein. The method (400) includes initiating (block 401) a number of pre-access operations. A pre-access operation is an operation by which a pre-access voltage is applied to a number of first lines (FIG. 2, 214) and second lines (FIG. 2, 216) to determine a sneak current throughout the crossbar array (FIG. 1, 110). In some examples, the pre-access operation may be initiated (block 401) by a pre-access engine (FIG. 1, 106) which may be implemented as circuitry as indicated in FIG. 3B or as a component of the memory controller (FIG. 1, 102) as depicted in FIG. 3A. When implemented as circuitry, the pre-access engine (FIG. 1, 106) may initiate (block 401) a pre-access operation based on heuristics such as after a set number of accesses have been executed for the crossbar array (FIG. 1, 110) or a particular second line (FIG. 2, 216) of the crossbar array (FIG. 1, 110).

In some examples, the pre-access operation may be initiated (block 401) by receiving a pre-access command from a memory controller (FIG. 1, 102). For example, using information about at least one of a read queue, a write queue, a read history, a write history, a change to the characteristics of the crossbar array (FIG. 1, 110) (such as temperature), and other characteristics of the crossbar array (FIG. 1, 110), the pre-access engine (FIG. 1, 106) as part of the memory controller (FIG. 1, 102) may issue a pre-access command. In some examples, each pre-access operation may be speculative and may be unused when determining an element current. For example, a stored sneak current may expire after a set period of time or after having been accessed a set number of times (for example to calculate an element current), and may also not be valid after a change to the crossbar array (FIG. 1, 110). In this example, if the set period of time has expired, a new pre-access operation may be initiated (block 401) before the determined sneak current is used to determine an element current. In other words, a number of pre-access operations may be initiated (block 401) before an access command is received. Decoupling the pre-access operation from a received access command may afford a memory controller (FIG. 1, 102) more flexibility in scheduling pre-access operations as well as improving access latency as only an access current, and not a sneak current, is determined after a access request is received.

Initiating (block 401) the pre-access operation may be based on a determination that the crossbar array (FIG. 1, 110) is idle. As used in the present specification and in the appended claims a crossbar array (FIG. 1, 110) that is idle is one that is not actively subject to an access operation such as a read operation or a write operation and that is not likely to be subject to an access operation for a predetermined period of time. Determining that a crossbar array (FIG. 1, 110) is idle may include determining that a crossbar array (FIG. 1, 110) has been idle for a certain period of time or is likely to remain idle for a period of time. For example, a memory controller (FIG. 1, 102) may determine that the crossbar array (FIG. 1, 110) is idle by analyzing at least one of past read requests, past write requests, requests in a read queue, and requests in a write queue among other historical data. The memory controller (FIG. 1, 110) may also analyze predicted information to determine how long a crossbar array (FIG. 1, 110) is likely to be idle.

Determining a period of time when the crossbar array (FIG. 1, 110) is idle allows for determination of sneak current during an “off-peak” time, such “off-peak” time being a period of time when a read operation or write operation is not being executing. Calculating sneak current may be a computationally expensive and time consuming process. Accordingly, calculating the sneak current at an off-peak time reduces the operations that are carried out during a time when processing power is being consumed at higher levels and when quick responses are desired, such as during a read operation or a write operation; thus increasing the efficiency of a read and write operation. In other words, determining a period of time when the crossbar (FIG. 1, 110) is idle and determining sneak current in that period of time may reduce access latency and reduce access energy of crossbar arrays (FIG. 1, 110). Moreover, the determination of this time period as well as sneak current calculation therein may allow the system (FIG. 1, 100) more flexibility in scheduling of different operations.

Each pre-access operation may include a number of operations. For example, each pre-access operation may include discarding (block 402) a previously stored sneak current, determining (block 403) a new sneak current for the crossbar array (FIG. 1, 110), and storing (block 404) the sneak current, and.

The method (400) may include discarding (block 402) a previously stored sneak current. For example, as described above, the initiation (block 401) of pre-access operations may be speculative and not associated with a particular access request. Accordingly, events may occur that trigger a new pre-access operation initialization (block 401). When a new pre-access operation is initialized (block 401), a previously stored sneak current is discarded (block 402) so that a new sneak current is determined (block 403) and stored (block 404) such that the most recent, and accurate measure of sneak current will be used in determining an element current.

Determining (block 403) a new sneak current may include applying a pre-access voltage to a number of first lines (FIG. 2, 214) and a number of second lines (FIG. 2, 216) of the crossbar array (FIG. 1, 110) and collecting the resultant current. For example, a pre-access voltage of at most half of an access voltage (i.e., half of a read voltage or half of a write voltage) is applied to the first lines (FIG. 2, 214) and non-target second lines (FIG. 2, 216-2); the target second line (FIG. 2, 216-1) being grounded. In another example, during a pre-access operation, the first lines (FIG. 2, 214) and non-target second lines (FIG. 2, 216-2) may be floated.

Referring to FIG. 4, by passing a non-access voltage of half of the access voltage, for example V/2, to the first lines (FIG. 2, 214) and non-target second lines (FIG. 2, 216-2), and by applying zero potential to the target second line (FIG. 2, 216-1) the voltage drop across partially-selected memory elements (FIG. 2, 212-2) has a maximum value of V2. Being that a selector (FIG. 3, 318) may have a threshold voltage of greater than V/2, an applied non-access voltage of less than V/2 would not be sufficient to allow current to flow through the selector (FIG. 3, 318) and through a corresponding memory element (FIG. 2, 212). However, even so doing, a leak current may still flow through the crossbar array (FIG. 1, 110). The current in a crossbar array (FIG. 1, 110) collected due to the application of the pre-access voltage may be referred to as a sneak current. As the pre-access operation is initiated (block 401) prior to an access command, the sneak current may also be determined (block 403) prior to reception of a request to read the current of a memory element (FIG. 2, 212).

The method (400) includes storing (block 404) the new sneak current for a target second line (FIG. 2, 216-1) of the crossbar array (FIG. 1, 110). As described above, currents may be collected along second lines (FIG. 1, 116) (such as column lines) of the crossbar array (FIG. 1, 110). The current acquired may reflect the applied pre-access voltages along the first lines (FIG. 2, 214) and the resistances of various memory elements. For example, a sneak current may be reflective of the pre-access voltage applied to the first lines (FIG. 2, 214) as well as the resistances of memory elements (FIG. 2, 212) that see the pre-access voltages and which are passed along a second line (FIG. 2, 216) to the sensing circuitry (FIG. 3, 309). In some examples, the system (FIG. 1, 100) may include a sample and hold circuit in the sensing circuitry (FIG. 3, 309) to store multiple sneak currents corresponding to the multiple second lines (FIG. 2, 216). For example, a memory sub-array may include a single sample and hold circuit to store sneak currents for all the second lines (FIG. 2, 216) in the sub-array. In other examples, the system (FIG. 1, 100) may include multiple sample and hold circuits to store the multiple sneak currents corresponding to the multiple second lines (FIG. 2, 216). For example, a memory sub-array may include multiple sample and hold circuits (either less than or equal to the number of second lines (FIG. 2, 216)).

The method (400) includes applying (block 405), in response to a received access command, an access voltage across a target memory element (FIG. 2, 212-1) in a crossbar array (FIG. 1, 110). This may be done by applying (block 405) an access voltage across the target memory element (FIG. 2, 212-1). Accordingly, in this example, a portion of the access voltage may be applied (block 405) to the target first line (FIG. 2, 214-1) and target second line (FIG. 2, 216-1) to effectuate a voltage potential across the target memory element (FIG. 2, 212-1) at least equal to the access voltage. In one example, the target second line (FIG. 2, 216-1) may be grounded while an access voltage value “V” may be applied to the target first line (FIG. 2, 214-1). The voltage drop across the target memory element (FIG. 2, 212-1) generates a current that is collected by the sensing circuitry (FIG. 3, 309). The current collected by the sensing circuitry (FIG. 3, 309) that is based on the access voltage may be referred to as an access current. The access current may include an element current that refers to a current seen by the target memory element (FIG. 2, 212-1) as well as a sneak current that results from partially-selected and unselected memory elements (FIG. 2, 212-2, 212-3) that see some voltage drop that is less than a voltage drop effectuated by the access voltage.

To separate the element current from the sneak current, the method (400) includes determining (block 406) an element current for the target memory element (FIG. 2, 212-1) based on the access current and a stored sneak current. In some examples, this may include subtracting the stored sneak current from the access current. Such subtraction may separate the current flowing over a target memory element (FIG. 2, 212-1) from other currents detected during an access operation, currents which obfuscate the element current.

A method (400) of decoupling a pre-access operation from a later read or write operation, and determining the element current by subtracting the sneak current from the access current may remove the obfuscating effects of sneak current from the intended current used to determine the resistance state, and logical value, indicated by a memory element (FIG. 2, 212) such as a memristor. Such a method (400) may increase the effectiveness of read and write operations as well as increasing the response time to get such values by performing costly sneak current calculations at a time when a crossbar array (FIG. 1, 110) is otherwise unused. While FIG. 4 depicts operations being performed in a particular order, the method (400) operations may be performed in any order, or concurrently.

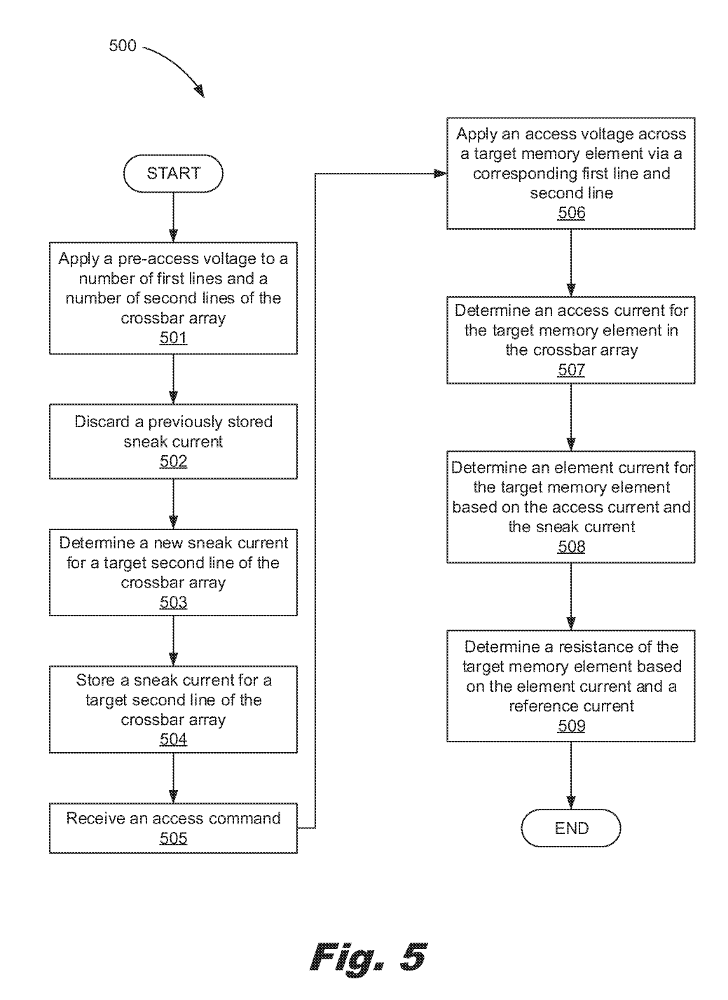

FIG. 5 is a flowchart of a method (500) for determining a current in a memory element (FIG. 2, 212) of a crossbar array (FIG. 1, 110), according to another example of the principles described herein. The method (500) includes applying (block 501) a pre-access voltage across a memory element (FIG. 2, 212) via a number of first lines (FIG. 2, 214) and a number of second lines (FIG. 2, 216) of the crossbar array (FIG. 1, 110). This may be performed as described above in connection with FIG. 4. The method (500) includes discarding (block 502) a previously stored sneak current. This may be performed as described above in connection with FIG. 4.

The method (500) includes determining (block 503) a new sneak current for the target second line (FIG. 2, 216-2) of the crossbar array (FIG. 1, 110). Determining (block 503) a new sneak current may include opening the sensing circuitry (FIG. 3, 309) to detect any current that passes through the target second line (FIG. 2, 216-1) responsive to pre-access voltages applied to the first lines (FIG. 2, 214) and non-target second lines (FIG. 2, 216-2). For example, as a pre-access voltage is passed to the lines, a sneak current may be generated along the target second line (FIG. 2, 216-2). This sneak current may be collected by the sensing circuitry (FIG. 3, 309) and passed to the sample and hold circuit to be stored (block 503). Storing (block 504) the new sneak current for the target second line (FIG. 2, 216-2) of the crossbar array (FIG. 1, 110) may be performed as described above in connection with FIG. 4.

The method (500) includes receiving (block 505) an access command. The access command may be a request to write information to a target memory element (FIG. 2, 212-1) or to read information from a target memory element (FIG. 2, 212-1). After an access command is received (block 505), an access voltage is applied (block 506) across a target memory element (FIG. 2, 212-1) via a corresponding target first line (FIG. 2, 214-1) and a target second line (FIG. 2, 216-1). In this example, applying a pre-access voltage (block 501) to a number of first lines (FIG. 2, 214) and a number of second lines (FIG. 2, 216) of the crossbar array (FIG. 1, 110) is performed before an access command is received (block 505). By comparison, applying (block 506) an access voltage; determining an access current (block 507); and determining (block 508) an element current may be performed in response to, or after an access command is received (block 505).

Applying (block 506) an access voltage to a target memory element (FIG. 2, 212-1) may include passing a portion of the access voltage via the target first line (FIG. 2, 214-1) and passing a second portion of the access voltage via the target second line (FIG. 2, 216-1) such that a voltage potential across the target memory element (FIG. 2, 212-1) is greater than a threshold voltage of the selector (FIG. 2, 218) that corresponds to the target memory element (FIG. 2, 212-1). At the same time a non-access voltage, which may equal the pre-access voltage, may be applied via the non-target first lines (FIG. 2, 214-2) and the non-target second lines (FIG. 2, 216-2). Applying a non-access voltage to non-target lines (FIG. 2, 214-2, 216-2) may be beneficial by reducing the size of a sneak current throughout the crossbar array (FIG. 1, 110).

The method (500) includes determining (block 507) an access current for the target memory element (FIG. 2, 212-1) in the crossbar array (FIG. 1, 110). This may be performed as described above in connection with FIG. 4.

The method (500) includes determining (block 508) an element current for the target memory element (FIG. 2, 212-1) based on the access current and the sneak current. This may include subtracting the sneak current from the access current.

The method (500) includes determining (block 509) a resistance of the target memory element (FIG. 2, 212-1) based on the element current and a reference current. For example, a number of reference current sources may output a number of reference currents. The sensing circuitry (FIG. 3, 309) may compare the reference currents to the element current and a number of output voltages generated when the element currents equal the reference currents. While FIG. 5 depicts operations being performed in a particular order, the method (500) operations may be performed in any order, or concurrently.

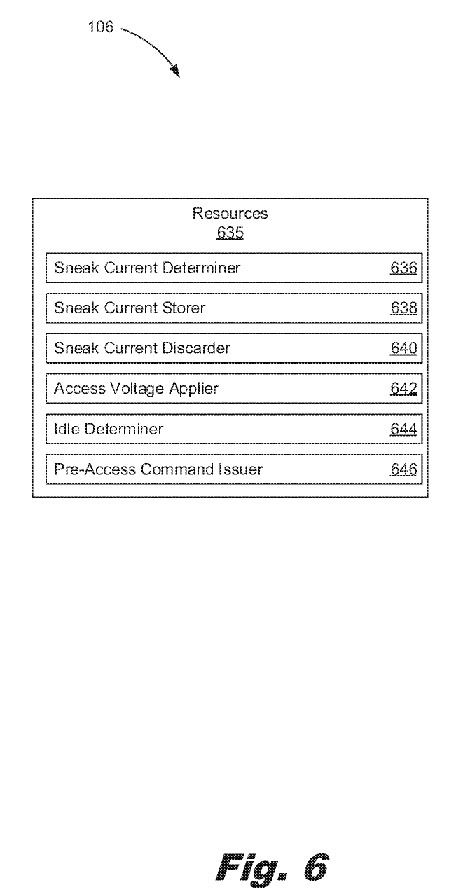

FIG. 6 is a diagram of the pre-read engine (106) for determining a current in a memory element (FIG. 2, 212) of a crossbar array (FIG. 1, 110), according to one example of the principles described herein. In an example, the pre-read engine (106) may be part of a memory controller (FIG. 1, 102) that is in communication with the resources (635). The memory controller (FIG. 1, 102) includes at least one processor and other resources used to process programmed instructions. The memory controller (FIG. 1, 102) may include the hardware architecture to retrieve executable instructions from the resources and execute the executable instructions. The executable instructions may, when executed by the memory controller (FIG. 1, 102), cause the memory controller (FIG. 1, 102) to determining a current through a memory element (FIG. 2, 212) in a crossbar array (FIG. 1, 110).

If the pre-read engine (106) is included in the memory controller (FIG. 1, 102), the resources (635) may be memory resources. The memory resources may store data such as executable instructions that are executed by the memory controller (FIG. 1, 102) or other processing device. As will be discussed, the memory resources may specifically store instructions representing a number of applications that the memory controller (FIG. 1, 102) executes to implement at least the functionality described herein.

The memory resources may include a machine readable medium, a machine readable storage medium, or a non-transitory machine readable medium, among others. For example, the memory resources may be, an electronic, magnetic, optical, electromagnetic, infrared, or semiconductor system, apparatus, or device, or any suitable combination of the foregoing. In the context of this document, a machine readable storage medium may be any tangible medium that can contain, or store machine readable instructions for use by or in connection with an instruction execution system, apparatus, or device. In another example, a machine readable storage medium may be any non-transitory medium that can contain, or store a program for use by or in connection with an instruction execution system, apparatus, or device.

A non-exhaustive list of machine readable storage medium types includes non-volatile memory, volatile memory, random access memory, memristor based memory, write only memory, flash memory, electrically erasable program read only memory, magnetic storage media, other types of memory, or combinations thereof. Many other types of memory may also be utilized, and the present specification contemplates the use of many varying type(s) of memory in the memory resources as may suit a particular application of the principles described herein. In certain examples, different types of memory in the memory resources may be used for different data storage needs.

The memory resources represent generally any memory capable of storing data such as programmed instructions or data structures used by the device (100).

If the pre-read engine (106) is included in the memory (108), the resources (635) may be circuitry components that carry out the functions.

The resources include a sneak current determiner (636), a sneak current storer (638), a sneak current discarder (640), an access voltage applier (642), an idle determiner (644), and a pre-access command issuer (646).

The sneak current determiner (636) represents programmed instructions, or circuitry that cause the system (FIG. 1, 100) to, during a pre-read operation, determine a sneak current for the crossbar array (FIG. 1, 110). The sneak current storer (638) represents programmed instructions, or circuitry that cause the system (FIG. 1, 100) to, during a pre-read operation, store the sneak current. The sneak current discarder (640) represents programmed instructions, or circuitry that cause the system (FIG. 1, 100) to, during a pre-read operation, discard a previously stored sneak current.

The access voltage applier (642) represents programmed instructions, or circuitry that cause the system (FIG. 1, 100) to apply an instruct an access voltage to be applied across a target memory element (FIG. 2, 212-1) to determine an element current for the target memory element (FIG. 2, 212-1) based on an access current and a stored sneak current.

The idle determiner (644) represents programmed instructions, or circuitry that cause the system (FIG. 1,100) to determine that a crossbar array (FIG. 1, 110) is idle. The pre-access command issuer (646) represents programmed instructions, or circuitry that cause the system (Fig., 100) to issue a pre-access command when the crossbar array (FIG. 1, 110) is idle.

Further, the memory resources may be part of an installation package. In response to installing the installation package, the programmed instructions of the memory resources may be downloaded from the installation package's source, such as a portable medium, a server, a remote network location, another location, or combinations thereof. Portable memory media that are compatible with the principles described herein include DVDs, CDs, flash memory, portable disks, magnetic disks, optical disks, other forms of portable memory, or combinations thereof. In other examples, the program instructions are already installed. Here, the memory resources can include integrated memory such as a hard drive, a solid state hard drive, or the like.

In some examples, the memory controller (FIG. 1, 102) and the memory resources are located within the same physical component, such as a server, or a network component. The memory resources may be part of the physical component's main memory, caches, registers, non-volatile memory, or elsewhere in the physical component's memory hierarchy. Alternatively, the memory resources may be in communication with the memory controller (FIG. 1, 102) over a network. Further, the data structures, such as the libraries and may be accessed from a remote location over a network connection while the programmed instructions are located locally. Thus, the pre-access engine (106) may be implemented on a user device, on a server, on a collection of servers, or combinations thereof.

The pre-read engine (106) of FIG. 6 may be part of a general purpose computer. However, in alternative examples, the pre-read engine (106) is part of an application specific integrated circuit.

Aspects of the present system and method are described herein with reference to flowchart illustrations and/or block diagrams of methods, apparatus (systems) and instruction sets according to examples of the principles described herein. Each block of the flowchart illustrations and block diagrams, and combinations of blocks in the flowchart illustrations and block diagrams, may be implemented by machine readable instructions. The machine readable instructions may be provided to a memory controller (FIG. 1, 102) of a general purpose computer, special purpose computer, or other programmable data processing apparatus to produce a machine, such that the machine readable instructions, when executed via, for example, the memory controller (FIG. 1, 102) or other programmable data processing apparatus, implement the functions or acts specified in the flowchart and/or block diagram block or blocks. In one example, the machine readable instructions may be embodied within a machine readable storage medium; the machine readable storage medium being part of the computer program product. In one example, the machine readable storage medium is a non-transitory machine readable medium.

The preceding description has been presented to illustrate and describe examples of the principles described. This description is not intended to be exhaustive or to limit these principles to any precise form disclosed. Many modifications and variations are possible in light of the above teaching.

What is claimed is:

1. A method comprising:
initiating a number of pre-access operations, for each pre-access operation:
discarding a previously stored sneak current;
determining a new sneak current for the crossbar array; and
storing the new sneak current;
in response to a received access command:
applying an access voltage across a target memory element of the crossbar array; and
determining an element current for the target memory element based on an access current and a stored sneak current.

2. The method of claim 1, in which the number of pre-access operations are initiated by a memory controller.

3. The method of claim 1, in which the number of pre-access operations are initiated by circuitry of the crossbar array.

4. The method of claim 1, in which a pre-access operation is a speculative operation.

5. The method of claim 1, in which determining a sneak current is performed before an access command is received.

6. A system comprising:
a crossbar array of memory elements, the crossbar array comprising:
a number of first lines;
a number of second lines intersecting the first lines, a memory element located at each intersection of a first line and a second line;
sensing circuitry coupled to the number of second lines to determine an element current for a memory element by subtracting a sneak current from an access current;
a memory controller communicatively coupled to the crossbar array, wherein the memory controller initiates an access operation; and
a pre-access engine to initiate a pre-access operation, separate from an access operation, to determine a sneak current for the crossbar array.

7. The system of claim 6, in which the pre-access engine includes circuitry.

8. The system of claim 7, in which the pre-access engine initiates a pre-access operation based on a number of heuristics.

9. The system of claim 6, in which the pre-access engine is part of the memory controller.

10. The system of claim 9, in which the pre-access engine issues a pre-access command based on information about past requests, future requests, or combinations thereof.

11. The system of claim 9, in which the pre-access engines issues a pre-access command after a change has occurred to the crossbar array.

12. The system of claim 9, in which the pre-access engine issues a pre-access command after at least one of a set period of time and after a stored sneak current has been used a set number of times to calculate an element current.

13. The system of claim 6, in which the sensing circuitry comprises a number of sample and hold circuits to store a sneak current associated with the target second line.

14. A non-transitory machine-readable storage medium encoded with instructions executable by a memory controller, the machine-readable storage medium comprising:
instructions to, during a pre-access operation, discard a previously stored sneak current;
instructions to, during a pre-access operation, determine a new sneak current for the crossbar array;
instructions to, during a pre-access operation, store the new sneak current; and
instructions to, in response to an access command, apply an access voltage to a target memory element to determine an element current for the target memory element based on an access current and a stored sneak current.

15. The non-transitory machine-readable storage medium of claim 14, in which the machine-readable storage medium comprises:
instructions to determine that a crossbar array is idle; and
instructions to issue a pre-access command when the crossbar array is idle.
